(19) United States
(12) Patent Application Publication
(10) Pub. No.: US 2023/0047118 A1
(43) Pub. Date: Feb. 16, 2023

(54) RADIATION-EMITTING SEMICONDUCTOR CHIP AND METHOD FOR PRODUCING A RADIATION-EMITTING SEMICONDUCTOR CHIP

(71) Applicant: OSRAM Opto Semiconductors GmbH, Regensburg (DE)

(72) Inventors: Matin MOHAJERANI, Regensburg (DE); Zeynep Meric-Polster, Regensburg (DE); Martin Behringer, Regensburg (DE); Berthold Hahn, Hemau - Hohenschambach (DE)

(21) Appl. No.: 17/793,049

(22) PCT Filed: Jan. 7, 2021
(86) PCT No.: PCT/EP2021/050167

§ 371 Date: Jul. 15, 2022

(30) Foreign Application Priority Data
Jan. 21, 2020 (DE) 10 2020 200 621.0

(51) Int. Cl. H01L 33/62; H01L 27/15; H01L 33/40; H01L 33/48

(52) U.S. Cl. CPC H01L 33/62; H01L 27/156; H01L 33/405; H01L 33/486; H01L 2933/0016; H01L 2933/0033; H01L 2933/0066

(57) ABSTRACT

A radiation-emitting semiconductor chip may include a semiconductor layer sequence having a first semiconductor layer and a second semiconductor layer, a first metallic mirror with which charge carriers can be embedded into the first semiconductor layer, a first metallic contact layer disposed atop the first metallic mirror, and a second metallic contact layer disposed atop the first metallic contact layer. A first seed layer may be disposed between the first metallic contact layer and the first metallic mirror. A second seed layer may be disposed between the first metallic contact layer and the second metallic contact layer. The radiation-emitting semiconductor chip may include a radiation exit face having a multitude of emission regions. The first metallic mirror may have a multitude of cutouts that each define a lateral extent of one of the emission regions.

### CROSS-REFERENCE TO RELATED APPLICATIONS

The present application is a national stage entry according to 35 U.S.C. §371 of PCT application No.: PCT/EP2021/050167 filed on Jan. 7, 2021; which claims priority to German patent application DE 10 2020 200 621.0, filed on Jan. 21, 2020; all of which are incorporated herein by reference in their entirety and for all purposes.

### TECHNICAL FIELD

A radiation-emitting semiconductor chip and a method of producing a radiation-emitting semiconductor chip are specified.

### BACKGROUND

One problem addressed is that of specifying a radiation-emitting semiconductor chip having particular mechanical stability. A method of producing such a radiation-emitting semiconductor chip is also to be specified.

For example, the radiation-emitting semiconductor chip is designed to emit electromagnetic radiation in operation. The electromagnetic radiation emitted by the radiation-emitting semiconductor chip may be near-ultraviolet radiation, visible light and/or near-infrared radiation.

The radiation-emitting semiconductor chip has, for example, a main plane of extension. A vertical direction extends at right angles to the main plane of extension, and lateral directions extend parallel to the main plane of extension.

### SUMMARY

In at least one embodiment, the radiation-emitting semiconductor chip comprises a semiconductor layer sequence having a first semiconductor layer and a second semiconductor layer. For example, the semiconductor layer sequence has been grown epitaxially onto a growth substrate. The semiconductor layer sequence is based, for example, on a III-V compound semiconductor material. The III-V compound semiconductor material is, for example, a phosphide, arsenide and/or nitride compound semiconductor material, i.e., for example, InₓAl_{y}Ga₁₋ _{x-y}P, InₓAl_{y}Ga_{1-x-y}As and/or InₓAl_{y}Ga_{1-x-y}N with 0 ≤ × ≤ 1, 0 ≤ y ≤1 and x + y ≤1.

The semiconductor layer sequence may include dopants and additional constituents. For the sake of simplicity, however, only the essential constituents of the crystal lattice of the semiconductor layer sequence, i.e. Al, Ga, In, N, As or P, are specified, even though these may be replaced and/or supplemented by small amounts of further substances in regions.

The semiconductor layer sequence comprises a first semiconductor layer, for example of a first conductivity type, and a second semiconductor layer, for example of a second conductivity type different than the first conductivity type. For example, the first semiconductor layer is n-doped and hence n-conducting. In that case, the second semiconductor layer is p-doped and hence p-conducting.

The first semiconductor layer and the second semiconductor layer are, for example, stacked one on top of another in vertical direction. In addition, an active region may be disposed between the first semiconductor layer and the second semiconductor layer. The active region is designed, for example, to generate electromagnetic radiation. The active region has, for example, a pn junction, for example a heterostructure, a single quantum well structure or a multiple quantum well structure.

In at least one embodiment, the radiation-emitting semiconductor chip comprises a first metallic mirror with which charge carriers can be embedded into the first semiconductor layer. For this purpose, the first metallic mirror is connected in an electrically conductive manner to the first semiconductor layer. The first metallic mirror, for example, is in direct contact with the first semiconductor layer. Alternatively, it is possible that an electrically conductive layer is disposed between the first metallic mirror and the first semiconductor layer.

The first metallic mirror extends, for example, through the second semiconductor layer into the first semiconductor layer or toward the first semiconductor layer. The first metallic mirror penetrates the second semiconductor layer completely. The first semiconductor layer, for example, is not penetrated completely by the first metallic mirror.

The first metallic mirror extends, for example, along grid lines of a first regular grid. The first regular grid is, for example, a square grid.

The first metallic mirror, for example, includes or consists of an electrically conductive metal. More particularly, it is possible that the first metallic mirror comprises multiple layers. In this case, the layers of the first metallic mirror are stacked one on top of another in vertical direction. The metal of the first metallic mirror is, for example, one or more of the following materials: copper, gold, platinum, titanium, aluminum, silver.

The first metallic mirror, for example, is designed to reflect electromagnetic radiation, especially the electromagnetic radiation generated in the active region that hits the first metallic mirror, to an extent of at least 95%, especially to an extent of at least 98%.

In at least one embodiment, the radiation-emitting semiconductor chip comprises a first metallic contact layer disposed atop the first metallic mirror. In particular, the first metallic contact layer is arranged above the first metallic mirror in vertical direction. In top view, the first metallic contact layer covers large parts of the first metallic mirror. What is meant here and hereinafter by “large parts” is that the first metallic contact layer, in top view, covers at least 80%, especially at least 90%, but less than 100%, of the first metallic mirror. This means that a cross-sectional area in lateral directions of the first metallic contact layer is, for example, less than a cross-sectional area in lateral directions of the first metallic mirror.

The first metallic contact layer, for example, includes or consists of an electrically conductive metal. The electrically conductive metal is, for example, one of the following materials: copper, nickel.

In at least one embodiment, the radiation-emitting semiconductor chip comprises a second metallic contact layer disposed atop the first metallic contact layer. More particularly, the second metallic contact layer is disposed above the first metallic contact layer in vertical direction. The second metallic contact layer is disposed atop the first metallic contact layer, for example, exclusively in an outer region of the radiation-emitting semiconductor chip. The outer region extends, for example, along outer gridlines of the first regular grid. The outer gridlines in this case are the outermost gridlines that are each disposed at an edge of the first regular grid.

For example, the second metallic contact layer is contactable from the outside. This means that the second metallic contact layer is especially a connection layer via which an electrical current can be embedded into the first semiconductor layer via the first metallic contact layer and the first metallic mirror.

The second metallic contact layer, for example, includes or consists of an electrically conductive metal. For example, the second metallic contact layer is formed by the same material as the first metallic contact layer.

The first metallic contact layer and/or the second metallic contact layer has, for example, an extent in vertical direction of at least 1 µm and at most 20 µm, especially of at least 3 µm and at most 10 µm. For example, the first metallic contact layer and the second metallic contact layer do not have the same extent in vertical direction.

In at least one embodiment of the radiation-emitting semiconductor chip, a first seed layer is disposed between the first metallic contact layer and the first metallic mirror. The first seed layer, for example, is in direct contact with the first metallic contact layer and the first metallic mirror. The first seed layer has an extent in lateral directions which, for example, is at least as great as an extent in lateral directions of the first metallic contact layer. Alternatively, the first seed layer surmounts the first metallic contact layer in lateral directions.

The first seed layer, for example, includes or consists of an electrically conductive metal. A seed layer is designed, for example, such that a metallic layer can be grown onto it. The seed layer, for example, forms crystallization seeds for the metal layer that can be grown onto it. More particularly, it is possible for the seed layer to have sublayers. The sublayers of the first seed layer, for example, are stacked one on top of another in vertical direction. The metal of the first seed layer is, for example, one or more of the following materials: titanium, platinum, gold.

In at least one embodiment of the radiation-emitting semiconductor chip, a second seed layer is disposed between the first metallic contact layer and the second metallic contact layer. The second seed layer, for example, is in direct contact with the first metallic contact layer and the second metallic contact layer. The second seed layer has an extent in lateral directions which, for example, is just as great as an extent in lateral directions of the first metallic contact layer.

The second seed layer, for example, includes or consists of an electrically conductive metal. More particularly, the second seed layer is formed by the same materials as the first seed layer.

In at least one embodiment, the radiation-emitting semiconductor chip comprises a semiconductor layer sequence having a first semiconductor layer and a second semiconductor layer, a first metallic mirror with which charge carriers can be embedded into the first semiconductor layer, a first metallic contact layer disposed atop the first metallic mirror, and a second metallic contact layer disposed atop the first metallic contact layer. Additionally disposed between the first metallic contact layer and the first metallic mirror is a first seed layer, and between the first metallic contact layer and the second metallic contact layer is disposed a second seed layer.

One idea associated with the radiation-emitting semiconductor chip described here is that a first metallic contact layer and a second metallic contact layer are disposed atop the first metallic mirror. By virtue of the first metallic contact layer and the second metallic contact layer, each of which comprise nickel for example, such a radiation-emitting semiconductor chip is advantageously formed in a particularly stable manner.

It is possible that use of the first metallic contact layer and of the second metallic contact layer makes it possible to dispense with further mechanically stabilizing supports. Advantageously, the radiation-emitting semiconductor chip can thus be formed so as to be particularly thin. Such a radiation-emitting semiconductor chip has, for example, an extent in vertical direction of at least 5 µm and at most 20 µm.

In at least one embodiment, the radiation-emitting semiconductor chip comprises a multitude of second metallic mirrors, with each of which charge carriers can be embedded into the second semiconductor layer. For example, the second metallic mirrors are spaced apart in lateral directions. The second metallic mirrors are arranged, for example, at grid points of a second regular grid. In this case, the second metallic mirrors are arranged in the manner of a matrix, especially along rows and columns. The second regular grid may, for example, be a square grid. The grid points of the second regular grid are disposed, for example, between the gridlines of the first regular grid.

The second metallic mirrors, for example, include or consist of an electrically conductive metal. More particularly, it is possible that the second metallic mirrors each comprise multiple layers. In this case, the layers of the second metallic mirrors are stacked one on top of another in vertical direction. The metal of the second metallic mirror is, for example, one or more of the following materials: copper, gold, platinum, titanium, aluminum, silver, nickel. For example, it is possible that the second metallic mirror is formed by the same material as the first metallic mirror.

The second metallic mirrors are designed, for example, to reflect electromagnetic radiation, especially the electromagnetic radiation generated in the active region that hits the second metallic mirror, to an extent of at least 95%, especially to an extent of at least 98%.

In at least one embodiment, the radiation-emitting semiconductor chip comprises a multitude of third metallic contact layers.

In at least one embodiment of the radiation-emitting semiconductor chip, one of the third metallic contact layers is disposed atop each of the second metallic mirrors. In particular, the third metallic contact layers are arranged above the second metallic mirrors in vertical direction. In top view, one of the third metallic contact layers in each case completely covers one of the second metallic mirrors. For example, one of the second metallic contact layers in each case covers one of the second metallic mirrors in lateral directions. This means that a cross-sectional area in lateral directions of one of the second metallic contact layers in each case is greater, for example, than a cross-sectional area in lateral directions of one of the second metallic mirrors.

For example, the third metallic contact layers are disposed at the grid points of the second regular grid.

The third metallic contact layers, for example, include or consist of an electrically conductive metal. For example, the third metallic contact layers are formed by the same material as the second metallic contact layer.

For example, the third metallic contact layers are contactable from the outside. This means that the third metallic contact layers are especially a connection layer via which an electrical current can be embedded into the second semiconductor layer via the second metallic mirrors.

In at least one embodiment of the radiation-emitting semiconductor chip, a third seed layer is disposed in each case between the third metallic contact layers and the second metallic mirrors. The third seed layers are, for example, in direct contact with the third metallic contact layers and the second metallic mirrors. One of the third seed layers in each case has an extent in lateral directions which, for example, is just as great as an extent in each case in lateral directions of one of the third metallic contact layers.

The third seed layers, for example, include or consist of an electrically conductive metal. More particularly, the third seed layers are formed by the same materials as the second seed layer.

In at least one embodiment of the radiation-emitting semiconductor chip, the radiation-emitting semiconductor chip comprises a radiation exit face having a multitude of emission regions.

In at least one embodiment of the radiation-emitting semiconductor chip, the first metallic mirror has a multitude of cutouts that each define a lateral extent of one of the emission regions.

It is possible that the active region of the semiconductor layer sequence comprises a multitude of subregions. Each subregion of the active region is designed, for example, to generate the electromagnetic radiation and emit it via an assigned emission region. In this case, each subregion of the active region is assigned a single emission region. The subregions, for example, are spaced apart in lateral directions. The spacing and especially also lateral extent of the subregions of the active region is defined by the first metallic mirror, which extends up to the first semiconductor layer, i.e. especially penetrates the active region.

For example, the cutouts are disposed at grid points of the second regular grid. The first metallic mirror in this case is structured and formed so as to be electrically coherent. One of the second mirrors in each case is disposed, for example, in one of the cutouts of the second metallic mirror. This means that each second metallic mirror is completely surrounded by the first metallic mirror in lateral directions. Current can be applied to an individual subregion of the active region, for example, through one of the two metallic mirrors and a portion of the adjoining first metallic mirror.

It is thus advantageously possible that current can be applied to the subregions of the active layer independently of one another. This means that the emission regions can emit electromagnetic radiation independently of one another.

More particularly, the portion of the first metallic layer that extends into the first semiconductor layer completely surrounds the subregions of the active layer in lateral directions. Thus, there is advantageously a reduction in crosstalk of electromagnetic radiation generated in adjacent subregions of the active layer. This means that contrast of different emission regions is thus particularly high.

In at least one embodiment of the radiation-emitting semiconductor chip, the second metallic contact layer surrounds all second metallic mirrors in lateral directions. The second metallic contact layer is disposed in lateral directions, for example, in the form of a frame around all second metallic mirrors. For example, the second metallic contact layer surrounds all third metallic contact layers in lateral directions.

In at least one embodiment of the radiation-emitting semiconductor chip, a first insulating layer is disposed between the first metallic mirror and/or the second metallic mirror and the semiconductor layer sequence. For example, the first insulating layer is disposed completely atop the second semiconductor layer. In this case, the first insulating layer is fully penetrated by the first metallic mirror and/or the second metallic mirror.

More particularly, the first insulating layer is electrically insulating. For example, it is possible that the first insulating layer has multiple sublayers. The sublayers are formed, for example, by semiconductor oxides and/or metal oxides and/or semiconductor nitrides and/or metal nitrides. For example, the first insulating layer comprises one or more of the following materials: SiNx, SiO₂.

In at least one embodiment, a further first insulating layer is disposed atop the first insulating layer and the first metallic mirror and/or the second metallic mirrors. For example, the further first insulating layer completely covers an outer face of the first insulating layer remote from the semiconductor layer.

In addition, the further first insulating layer covers regions, for example, of an outer face of the first metallic mirror remote from the semiconductor layer. The further first insulating layer in this case has, for example, a first opening in which the first seed layer is disposed. In this region, the first seed layer is in direct contact with the first metallic mirror.

In addition, the further first insulating layer covers regions in each case, for example, of an outer face of the second metallic mirrors remote from the semiconductor layer. The further first insulating layer in this case has a second opening above each of the second metallic mirrors, in each of which one of the third seed layers is disposed. In this region, the third seed layers are each in direct contact with the metallic second mirrors.

In at least one embodiment of the radiation-emitting semiconductor chip, an interlayer is disposed atop the first insulating layer. More particularly, an interlayer is disposed atop the further first insulating layer. In that case, the further first insulating layer is disposed between the interlayer and the first insulating layer. For example, the interlayer completely covers the further first electrically insulating layer between the first metallic contact layer and the third metallic contact layers.

For example, the interlayer is an antireflective layer. The interlayer is, for example, in electrically insulating form. The interlayer comprises, for example, semiconductor oxides and/or metal oxides and/or semiconductor nitrides and/or metal nitrides. For example, the interlayer comprises one or more of the following materials: SiNx, SiO₂.

In at least one embodiment of the radiation-emitting semiconductor chip, a second insulating layer is disposed between the first metallic contact layer and the third metallic contact layer. The second insulating layer covers interstices between the second metallic contact layer and the third metallic contact layers, for example completely. In addition, the second insulating layer covers interstices in the first metallic contact layer and the third metallic contact layers, for example completely.

The second insulating layer is, for example, a dielectric mirror layer. The second insulating layer comprises dielectric materials, for example. More particularly, it is possible that the second insulating layer comprises multiple sublayers. The sublayers of the second insulating layer are formed, for example, by semiconductor oxides and/or metal oxides and/or semiconductor nitrides and/or metal nitrides. For example, the second insulating layer comprises one or more of the following materials: SiNx, SiO₂.

The second insulating layer is designed, for example, to reflect electromagnetic radiation, especially the electromagnetic radiation generated in the active region that hits the second insulating layer, to an extent of at least 95%, especially to an extent of at least 98%.

In at least one embodiment of the radiation-emitting semiconductor chip, a current spreading layer is disposed between the second metallic mirror and the semiconductor layer sequence. For example, the current spreading layer is disposed atop the second semiconductor layer and covers it completely. In this case, the current spreading layer is penetrated by the first metallic mirror. The current spreading layer is in direct contact, for example, with the second metallic mirrors and the second semiconductor layer.

The current spreading layer includes, for example, electrically conductive metals or transparent, electrically conductive oxides (transparent conductive oxides, TCOs for short), or is formed from one of these materials. For example, zinc oxide, tin oxide, cadmium oxide, titanium oxide, indium oxide or indium tin oxide (ITOs) are TCOs. In general, TCOs are provided with a dopant. The dopant is generally designed to impart electrically conductive properties to the TCOs.

In at least one embodiment, a radiation exit face of the semiconductor layer sequence is free of any growth substrate. The growth substrate, for example, has been detached. For example, an outer face of the first semiconductor layer remote from the contact layers is free of the growth substrate. In this case, it is possible that an outer face of the semiconductor layer sequence remote from the contact layers, especially of the first semiconductor layer, is structured. Advantageously, such a radiation-emitting semiconductor chip has a particularly small extent in vertical direction.

In addition, it is possible that such a radiation-emitting semiconductor chip is not rigid. This means that the radiation-emitting semiconductor chip is advantageously designed to be slightly pliable. What is meant here by “slightly pliable” is that, for example, the radiation-emitting semiconductor chip has a modulus of elasticity of at most 200 GPa, especially at most 5 GPa.

Additionally specified is a method of producing a radiation-emitting semiconductor chip, by which a radiation-emitting semiconductor chip described here can be produced. All features and embodiments disclosed in connection with the radiation-emitting semiconductor chip are therefore also applicable in conjunction with the method and vice versa.

In at least one embodiment of the method, a first semiconductor layer sequence having a first semiconductor layer and a second semiconductor layer is provided.

In at least one embodiment of the method, a first recess that exposes a region of the first semiconductor layer is created. The first recess penetrates the second semiconductor layer, for example completely. For example, the first recess proceeds from the second semiconductor layer and extends into the semiconductor layer sequence. The first semiconductor layer is, for example, not completely penetrated by the first recess. The first recess, for example, exposes a region of the first semiconductor layer. This means that a floor of the first recess is formed by the first semiconductor layer. In addition, at least one lateral face of the first recess is formed, for example, by the first semiconductor layer and the second semiconductor layer.

For example, the first recess is removed by a first photoresist mask and an etching process, especially a dry ageing process.

After the first recess has been created, it dielectric mirror layer is applied in the first recess. The dielectric mirror layer, for example, completely covers the lateral faces of the first recess and the floors of the first recess. The dielectric mirror layer here, for example, does not completely fill the first recess. For example, the dielectric mirror layer is in direct contact with the first semiconductor layer, the second semiconductor layer and the reflective layer sequence in the region of the lateral face of the first recess. In addition, the dielectric mirror layer, for example, is in direct contact with the first semiconductor layer in the region of the floor of the first recess.

The dielectric mirror layer thus created is removed, for example, on the floor of the first recess such that the second semiconductor layer is exposed there. The removing of the dielectric mirror layer may be implemented via an anisotropic etching method. The anisotropic etching method, for example, has a higher etch rate in vertical direction than in lateral direction. Such an etching method, for example, completely removes the dielectric mirror layer in the region of the floor of the first recess, while the dielectric mirror layer remains on the lateral face of the first recess.

For example, the dielectric mirror layer after the etching process has a thickness in lateral direction of about 500 nanometers.

The dielectric mirror layer comprises, for example, a dielectric material, for instance SiO₂. An SiO₂ layer is applied, for example, by a plasma-enhanced chemical vapor deposition (“PECVD” for short) .

The dielectric mirror layer has, for example, a reflectance of at least 98%, especially of at least 99%, for the electromagnetic radiation generated in the active region that hits the dielectric mirror layer.

In at least one embodiment of the method, a first metallic mirror is created in the first recess. For example, the first metallic mirror completely fills the first recess. In addition, it is possible that the first metallic mirror surmounts the first recess in vertical direction. If the first metallic mirror some outs the first recess in vertical direction, the first metallic mirror will surmount the first recess, for example, in lateral directions as well.

The first metallic mirror is created, for example, by means of a third photoresist mask.

In at least one embodiment of the method, a first seed layer is applied to the first metallic mirror. For example, the first seed layer is applied completely over the semiconductor layer sequence by means of a sputtering process. Subsequently, the first seed layer is structured by photolithography, for example.

In at least one embodiment of the method, a first metallic contact layer is deposited on the first seed layer.

In at least one embodiment of the method, a second seed layer is applied atop the first metallic contact layer. The second seed layer may, for example, be applied completely over the semiconductor layer sequence by means of a sputtering process. Subsequently, the second seed layer may be structured by photolithography.

In at least one embodiment of the method, a second metallic contact layer is deposited on the second seed layer.

In at least one embodiment of the method, the first recess extends along grid lines of a first regular grid. In this case, the first metallic mirror also extends along the first regular grid.

In at least one embodiment of the method, a first insulating layer is applied atop the semiconductor layer sequence.

In at least one embodiment of the method, a multitude of second recesses is created in the first insulating layer, each of which expose regions of the second semiconductor layer. The second recesses, for example, each expose regions of the second semiconductor layer.

It is possible that a current spreading layer is disposed atop the second semiconductor layer and in direct contact therewith. In this case, a floor of the second recesses is formed by the current spreading layer. In addition, lateral faces of the second recess are formed, for example, by the first insulating layer.

For example, the second recesses are removed with a second photoresist mask and an etching process, especially a dry etching process.

In at least one embodiment of the method, a second metallic mirror is created in any one of the second recesses. For example, any one of the second metallic mirrors completely fills any one of the second recesses. In addition, it is possible that any one of the second metallic mirrors surmounts any one of the second recesses in vertical direction. If the second metallic mirrors surmount the second recesses in vertical direction, the second metallic mirrors will surmount the second recesses, for example, in lateral directions as well.

The second metallic mirrors are created, for example, by means of a fourth photoresist mask. Alternatively, it is possible that the first metallic mirror and the second metallic mirrors are created by means of a common photoresist mask.

In at least one embodiment of the method, a third seed layer is applied atop any one of the second metallic mirrors. For example, the second seed layer and the third seed layers are applied in a common process. In addition, it is possible that the second seed layer and the third seed layers are structured in a common process.

In at least one embodiment of the method, a metallic contact layer is deposited on any one of the third seed layers. For example, the second metallic contact layer and the third metallic contact layers are applied in a common process.

In at least one embodiment of the method, the second metallic contact layer and the third metallic contact layers are planarized. For example, the second metallic contact layer surmounts the third metallic contact layers in vertical direction after application. In this case, for example, the second metallic contact layer is removed such that a top face of the second metallic contact layer and a top face of the third metallic contact layers are in a common plane. For example, the second metallic contact layer and the third metallic contact layers are planarized by means of a grinding process.

In at least one embodiment of the method, the first metallic contact layer, the second metallic contact layer and/or the third metallic contact layers are deposited by means of electroplating. In the electroplating operation, the electrically conductive metal of the first metallic contact layer, of the second metallic contact layer and/or of the third metallic contact layer is deposited electrochemically on the respective seed layer. In this case, each of the seed layer is formed the crystallization seeds for the metallic contact layer deposited thereon.

In at least one embodiment of the method, one solder layer is applied atop the second metallic contact layer and one atop the third metallic contact layers. The solder layers each comprise, for example, a solderable metal or are formed from a solderable metal.

In at least one embodiment of the method, an auxiliary carrier is applied atop the second metallic contact layer and the third metallic contact layers. In particular, the auxiliary carrier is applied to the solder layers. For example, the auxiliary carrier is removed again after structuring of the radiation exit face.

In at least one embodiment of the method, a growth substrate of the semiconductor layer sequence is detached. For example, as a result of the application of the auxiliary carrier to the second metallic contact layer and the third metallic contact layers, the growth substrate may be detached.

### BRIEF DESCRIPTION OF THE DRAWINGS

The method of assembling a radiation-emitting semiconductor chip and the radiation-emitting semiconductor chip are elucidated in detail hereinafter by working examples and the associated figures.

The figures show: FIGS. 1, 2, 3, 4, 5, 6, 7, 8, 9, 10 and 11: schematic section diagrams of method stages in the production of a radiation-emitting semiconductor chip in one working example,

FIG. 12: schematic section diagram of a radiation-emitting semiconductor chip in one working example, and

FIGS. 13 and 14: schematic diagrams in top view of a radiation-emitting semiconductor chip in one working example.

Elements that are the same, of the same type or have the same effect are given the same reference numerals in the figures. The figures and size ratios of the elements shown in the figures with respect to one another should not be considered to be true to scale. Instead, individual elements, for better representability and/or for better comprehensibility, may be shown in excessively large size.

### DETAILED DESCRIPTION

In the method steps according to FIG. 1, a semiconductor layer sequence 2 with a first semiconductor layer 3 and a second semiconductor layer 4 is provided. A current spreading layer 8 is applied to the second semiconductor layer 4. The current spreading layer 8 is in direct contact with the second semiconductor layer 4. The current spreading layer 8 is formed by ITO, for example. In addition, the current spreading layer 8 has an extent in vertical direction of about 60 nm.

Subsequently, a first insulating layer 9 is applied atop the current spreading layer 8. The first insulating layer 9 has multiple sublayers. For example, one sublayer facing the semiconductor layer sequence 2 comprises SiO₂, with a height in vertical direction of about 600 nm. A sublayer remote from the semiconductor layer sequence 2 comprises, for example, SiNx with a height in vertical direction of about 20 nm.

In a further step, a multitude of second recesses 7 is created in the first insulating layer 9, each of which expose regions of the current spreading layer 8. For creation of second recesses 7, a photoresist, for instance hexamethyldisilazane (HMDS for short), with a height in vertical direction of about 6 µm, is applied to the first insulating layer 9. The photoresist is exposed in such a way that it forms a second photoresist mask. By means of the second photoresist mask, the first insulating layer 9 is removed by means of an etching process, especially a plasma etching process, such that regions of the current spreading layer 8 are exposed.

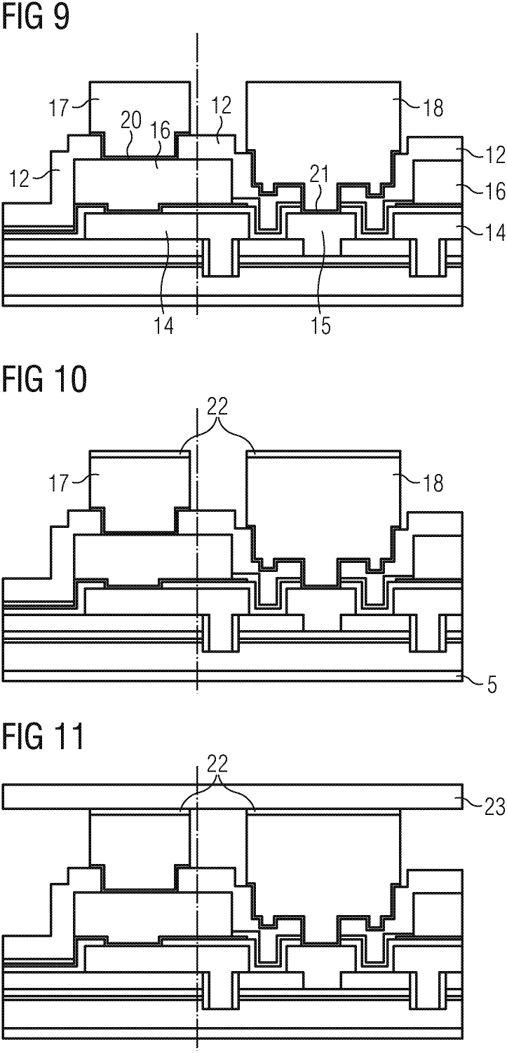

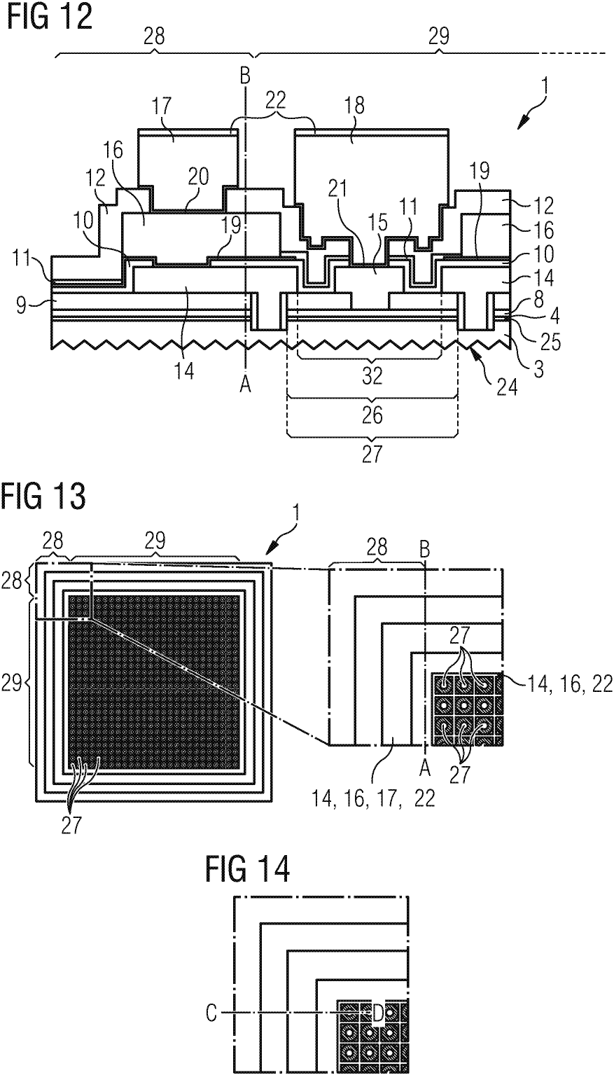

The second recesses 7 are disclosed at grid points of a second regular grid, as shown, for example, in conjunction with the working example of FIG. 13. The second regular grid is, for example, a square grid.

As shown in FIG. 2, a first recess 6 is created, which exposes regions of the first semiconductor layer 3. For creation of the first recess 6, a photoresist, for instance HMDS, with a height in vertical direction of about 6 µm, is applied to the first insulating layer 9 and the exposed current spreading layer 8. The photoresist is exposed in such a way that it forms a first photoresist mask. By means of the first photoresist mask, the first insulating layer 9, the current spreading layer 8, the second semiconductor layer 4 and the first semiconductor layer 3 are removed by means of an etching process, especially a plasma etching process, such that regions of the first semiconductor layer 3 are exposed. The first recess 6 has, for instance, a maximum extent in lateral directions of about 1.8 µm.

The first recess 6 extends along grid lines of a first regular grid. The first regular grid is especially a square grid.

In a further method stage, FIG. 3, after the creation of the first recess 6, a dielectric mirror layer 13 is applied in the first recess 6. After the application, the dielectric layer covers the lateral face and the floor of the first recess 6. In this working example, the dielectric mirror layer 13 is formed by SiO₂. The SiO₂ layer is applied here by a PECVD process. In “PECVD”, the dielectric mirror layer 13 is produced using tetraethyl orthosilicate (TEOS). The TEOS is the source of the silicon.

The dielectric mirror layer 13 thus created is removed at the floor of the first recess 6 such that the first semiconductor layer 3 is exposed there. The removing of the dielectric mirror layer 13 at the floor is implemented via anisotropic etching method. The dielectric mirror layer 13 after the etching process has a thickness in lateral direction of about 500 nanometers.

Subsequently, a first metallic mirror 14 is created in the first recess 6. In addition, a multitude of second metallic mirrors 15 is created in the second recesses 7.

The first metallic mirror 14 is created with a third photoresist mask. For example, a photoresist, for instance HMDS, is applied with a height in vertical direction of about 4.8 µm to the first insulating layer 9 and the exposed current spreading layer 8. The photoresist is exposed in such a way that it forms the third photoresist mask.

The second metallic mirrors 15 are created with a fourth photoresist mask.

The first mirror 14 and the second mirrors 15 comprising a layer sequence. For example, the layers of the layer, have the following layer sequence: 20 nm of ITO, 200 nm of Ag, 50 nm of Pt, 100 nm of Ti, 120 nm of Ni, 5 nm of Ti.

Once created, the first metallic mirror 14 completely fills the first recess 6. In addition, the first metallic mirror 14 surmounts the first recess 6 in vertical direction. The part of the metallic mirror 14 that surmounts the first recess 6 in vertical direction surmounts the first recess 6 in lateral directions as well. This means that the first metallic mirror 14 is disposed in regions of the first electrically insulating layer 9. The part of the first metallic mirror 14 disposed atop the first electrically insulating layer 9 is spaced apart in lateral directions from any of the parts of the second metallic mirrors 15 disposed atop the first electrically insulating layer 9. For example, the spacing in lateral directions is about 5 µm.

Once created, the second metallic mirrors 15 completely fill the second recesses 7. Any one of the second metallic mirrors 15 surmounts any one of the second recesses 6 in vertical direction and in lateral directions. This means that each of the second metallic mirrors 15 is disposed atop regions of the first electrically insulating layer 9.

In the method stage according to FIG. 4, a further first insulating layer 10 is applied atop the first insulating layer 9, the first metallic mirror 14 and the second metallic mirrors 15. The further first insulating layer 10 comprises, for example, SiNx and has a height in vertical direction of about 350 nm.

Subsequently, the further first insulating layer 10 is structured by means of a fifth photoresist layer in such a way that a first opening is created in the further first insulating layer 10. For creation of the first opening, a photoresist, for instance HMDS, with a height in vertical direction of about 8 µm, is applied to the first insulating layer 9, the first metallic mirror 14 and the second metallic mirrors 15. The photoresist is exposed in such a way that it forms the fifth photoresist mask. By means of a plasma etching process, the first opening is created.

The first opening here exposes regions of the first metallic mirror 14. The exposed region of the first metallic mirror 14 has a width in lateral directions of about 50 µm in the outer region. In addition, regions of the first metallic mirror 14 are exposed by the first recess in an inner region as well. The outer region 28 is described in detail, for example, in conjunction with FIG. 13.

In a further method stage according to FIG. 5, a photoresist, for instance HMDS, is applied with a height in vertical direction of about 3.9 µm atop the further first insulating layer 10 and the exposed first metallic mirror 14. The photoresist is exposed in such a way that it forms a sixth photoresist mask. The sixth photoresist mask here covers exclusively regions between the first metallic mirror 14 and the second metallic mirrors 15, and regions above the second metallic mirrors 15. Regions above the first metallic mirror 14 here are free of the sixth photoresist mask.

A first seed layer 19 is subsequently applied atop the sixth photoresist mask and the exposed regions. The first seed layer 19 here comprises three sublayers which, viewed from the first metallic mirror 14, have the following layer sequence: 20 nm of Ti, 20 nm of Pt, 200 nm of Au.

Subsequently, the sixth photoresist mask is removed, such that the first seed layer 19 is disposed above the region of the first metallic mirror 14.

In the method stage according to FIG. 6, an interlayer 11 is disposed atop the further first insulating layer 10 and the first seed layer 19. The seed layer 19 is disposed atop the first metallic mirror 14 in regions between the interlayer 11 and the first seed layer 19. The interlayer 11 is an antireflective layer comprising SiNx. The interlayer 11 has a height in vertical direction of about 20 nm and is applied by a chemical vapor deposition process (CVD).

Subsequently, a photoresist, for instance HMDS, is applied with a height in vertical direction of about 15 µm atop the interlayer 11. The photoresist is exposed in such a way that it forms a seventh photoresist mask. Regions on which a first metallic contact layer 16 is grown are not covered by the seventh photoresist mask. In these regions, the interlayer 11 is removed by means of an etching process in such a way that the first seed layer 19 is exposed.

In a further step, the first metallic contact layer 16 is created on the exposed first seed layer 19. Here, the first metallic contact layer 16 is deposited by means of electroplating. The first metallic contact layer 16 comprises Ni. After deposition, the first metallic contact layer 16 has an extent in the direction of about 10 µm.

Subsequently, it is possible that a Ti layer is deposited on a top face of the first metallic contact layer 16. The Ti layer is especially an adhesion promoter. The seventh photoresist mask is detached again after the application of the Ti layer.

In a further method stage according to FIG. 7, a second insulating layer 12 is disposed atop the interlayer 11 and the first metallic contact layer 16. The second insulating layer 12 is a dielectric mirror layer. The second insulating layer 12 comprises multiple sublayers. A sublayer facing the semiconductor layer sequence 2 comprises SiO₂ with a height and/or width of 660 nm, and a sublayer facing the semiconductor layer sequence 2 comprises SiNₓ with a height and/or width of 250 nm. The SiO₂ layer is applied here by a PECVD process using tetraethyl orthosilicate (TEOS).

Subsequently, a photoresist, for instance HMDS, is applied with a height in vertical direction of about 8 µm, atop the second insulating layer 12. The photoresist is exposed in such a way that it forms an eighth photoresist mask.

By means of the eighth photoresist mask, a third recess 30 and a multitude of fourth recesses 31 are created by a plasma etching process. The third recess 30 completely penetrates the second insulating layer 12 disposed above the first metallic contact layer 16, such that the third recess 30 exposes regions of the first metallic contact layer 16. In addition, any one of the fourth recesses 31 exposes regions of any one of the second metallic mirrors 15. Lateral faces of the fourth recesses 31 in this case are formed by the further first insulating layer 10, the interlayer 11 and the second insulating layer 12.

The third recess 30 has, for example, an extent in lateral directions of about 90 µm. Any one of the fourth openings 31 has, for example, an extent in lateral directions of about 10 µm.

In the method stage according to FIG. 8, a second seed layer 20 and third seed layers 21 are applied atop the second insulating layer 12, in the third recess 30 and in the fourth recesses 31. In this case, the second seed layer 20 and the third seed layers 21 are applied in a common process. The second seed layer 20 here is disposed above the first metallic contact layer 16, and the third seed layers 21 above the second metallic mirror 15. The second seed layer 20 in the third recess 30 is in direct contact with the first metallic contact layer 16. In addition, any one of the third seed layers 21 in any one of the fourth openings 31 is in direct contact with any one of the second metallic mirrors 15.

Subsequently, a photoresist having a height in vertical direction of about 75 µm is applied atop the second seed layer 20 and the third seed layers 21. The photoresist is exposed in such a way that it forms a ninth photoresist mask. A region in which a second metallic contact layer 17 is grown is not covered by the ninth photoresist mask. The second seed layer 20 is exposed in this region. In addition, regions in which the metallic contact layers 18 are grown are not covered by the ninth photoresist mask. The third seed layers 21 are exposed in these regions.

In a further step, the second metallic contact layer 17 is created on the exposed second seed layer 20. Here, the second metallic contact layer 17 is deposited by means of electroplating. The second metallic contact layer 17 comprises Ni. After deposition, the second metallic contact layer 17 has an extent in vertical direction of about 15 µm.

In the same process step in which the second metallic contact layer 17 is created, the third metallic contact layers 18 are created atop the exposed third seed layers 21. Here, the third metallic contact layers 18 are likewise deposited by means of electroplating. This means that the third metallic contact layers 18 also comprise Ni and each have an extent in vertical direction of about 15 µm.

Subsequently, the eighth photoresist layer is removed.

In the method stage of FIG. 9, the second seed layer 20 disposed alongside the second metallic contact layer 17 in lateral directions is removed by means of a wet-chemical etching process. In addition, the third seed layers 21 disposed alongside the third metallic contact layers 18 are removed by means of a wet-chemical etching process.

In a further step, the second metallic contact layer 17 and the third metallic contact layers 18 are planarized. For example, the second metallic contact layer 17 and the third metallic contact layers 18 are planarized by means of a grinding process in such a way that a top face of the second metallic contact layer 17 and a top face of the third metallic contact layers 18 are in a common plane.

Subsequently, it is possible that the top face of the second metallic contact layer 17 and the top face of the third metallic contact layers 18 are polished by means of a chemical-mechanical polishing process.

In the method stage according to FIG. 10, a solder layer 22 is applied atop the second metallic contact layer 17 and atop the third metallic contact layers 18. The solder layers 22 here comprise sublayers, for example. A sublayer of the solder layers 22 facing the semiconductor layer sequence 2 comprises Ni with an extent in vertical direction of about 10 nm, and a sublayer of the solder layers 22 remote from the semiconductor layer sequence 2 comprises Au with an extent in vertical direction of about 100 nm. The solder layers 22 each completely cover the outer face of the second metallic contact layer 17 and the outer face of the third metallic contact layers 18.

In a further method stage according to FIG. 11, an auxiliary carrier 23 is applied atop the second metallic contact layer 17 and the third metallic contact layers 18. Here, the auxiliary carrier 23 is applied to the solder layers 22. Subsequently, a growth substrate 5 of the semiconductor layer sequence 2 is detached.

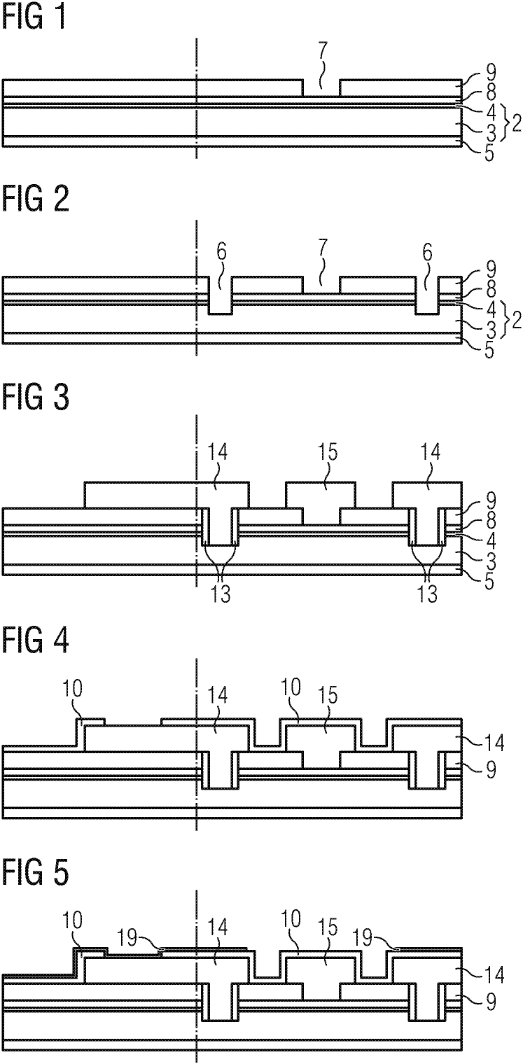

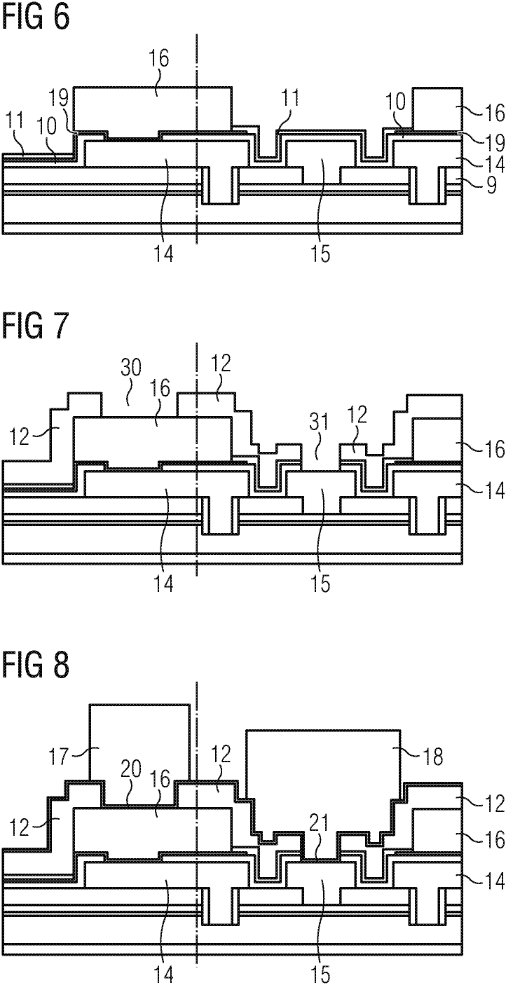

The radiation-emitting semiconductor chip 1 according to the working example of FIG. 12 may especially be produced by the method described in conjunction with FIGS. 1 to 11. The radiation-emitting semiconductor chip 1 has a semiconductor layer sequence 2 with a first semiconductor layer 3 and a second semiconductor layer 4. Between the first semiconductor layer 3 and the second semiconductor layer 4 is disposed an active region 25.

In addition, the radiation-emitting semiconductor chip 1 comprises a first metallic mirror 14 with which charge carriers can be embedded into the first semiconductor layer 3. Atop the first metallic mirror 14 is disposed a further first insulating layer 10 having a first opening. A first seed layer 19 is disposed in the first opening. The first seed layer 19 is also disposed in regions atop the further first insulating layer 10.

An interlayer 11 is also disposed in regions atop the first seed layer 19. The interlayer 11 here defines a lateral region of the first seed layer 19 on which a first metallic contact layer 16 is disposed.

Additionally disposed atop the first metallic contact layer 16 is a second insulating layer 12. In an outer region 28, the second insulating layer 12 has a third recess 30. In an inner region 29, the second insulating layer 12 covers the first metallic contact layer 16 completely. The outer region 28 and the inner region 29 are described in detail, for example, in conjunction with FIG. 13.

Disposed atop the first metallic contact layer 16 in the outer region 28 is a second seed layer 20. The second seed layer 20 is disposed in the third recess 30. In addition, the second seed layer 20 is disposed in regions atop the second insulating layer 12.

Disposed atop the second seed layer 20 is a second metallic contact layer 17. Disposed atop the second metallic contact layer 17 in turn is a solder layer 22.

Spaced apart in lateral directions from the first metallic mirror 14, the radiation-emitting semiconductor chip comprises second metallic mirrors 15 by which charge carriers can be embedded into the second semiconductor layer 4. Disposed atop the second metallic mirrors 15 in each case are the further first insulating layer 10, the interlayer 11 and the second insulating layer. In the further first insulating layer 10, the interlayer 11 and the second insulating layer, a fourth recess 31 is disposed in each case above the second metallic mirrors 15. A third seed layer 21 is disposed in each of the fourth openings 31. The third seed layers 21 are also disposed in regions atop the further first insulating layer 10.

A third metallic contact layer 18 is disposed atop each of the third seed layers 21. A solder layer 22 is disposed in turn atop each of the third metallic contact layers 18.

The first metallic mirror 14 extends in regions through the second semiconductor layer 2 into the first semiconductor layer 3. This means that the active region 25 is penetrated and structured by the first metallic mirror 14. The first metallic mirror 14 structures the active region 25 here in multiple subregions 26 of the active region 25. Each subregion 26 of the active region 25 is designed to generate electromagnetic radiation and to emit it via an assigned emission region 27. All emission regions 27 form a radiation exit face 24 of the radiation-emitting semiconductor chip 1.

The radiation-emitting semiconductor chip 1 in the working example of FIG. 13 comprises a multitude of emission regions 27 that are separated by the first metallic mirror 14 in lateral directions.

The first metallic mirror 14 and the first metallic contact element 16 extend along gridlines of a first regular grid. The emission regions 27 are disposed at grid points of a second regular grid. The grid points of the second regular grid are arranged here between the gridlines of the first regular grid. This means that the first metallic mirror 14 has a multitude of recesses 32, each of which defines a lateral extent of one of the emission regions 27.

The radiation-emitting semiconductor chip 1 has an outer region 28 and an inner region 29. The outer region 28 extends along outer gridlines of the first regular grid. The outer region 28 is spaced apart in lateral directions from the emission regions 27 of the radiation-emitting semiconductor chip 2. This means that the outer region 28 completely surrounds the emission regions 27 in the inner region 29 in lateral directions.

In addition, the line between points A and B indicates a section in vertical direction, the position of which is also shown in FIGS. 1 to 12.

In conjunction with FIG. 14, the dotted line between C and D indicates a section line in the schematic section diagrams according to FIGS. 1 to 12.

The features and working examples described in conjunction with the figures may be combined with one another in further working examples, even if not all combinations are explicitly described. In addition, the working examples described in conjunction with the figures may alternatively or additionally have further features according to the description in the general part.

The invention is not limited to the working examples by the description with reference thereto. Instead, the invention encompasses every new feature and every combination of features, which especially include any combination of features in the claims, even if this feature of this combination itself is not explicitly specified in the patent claims or working examples.

### LIST OF REFERENCE NUMERALS

1 radiation-emitting semiconductor chip
2 semiconductor layer sequence
3 first semiconductor layer
4 second semiconductor layer
5 growth substrate
6 first recess
7 second recess
8 current spreading layer
9 first insulating layer
10 further first insulating layer
11 interlayer
12 second insulating layer
13 dielectric mirror layer
14 first metallic mirror
15 second metallic mirror
16 first metallic contact layer
17 second metallic contact layer
18 third metallic contact layer
19 first seed layer
20 second seed layer
21 third seed layer
22 solder layer
23 auxiliary carrier
24 radiation exit face
25 active region
26 subregion of active region
27 emission region
28 outer region
29 inner region
30 third recess
31 fourth recess
32 cutout

1. A radiation-emitting semiconductor chip comprising:
a semiconductor layer sequence having a first semiconductor layer and a second semiconductor layer;
a first metallic mirror with which charge carriers can be embedded into the first semiconductor layer;
a first metallic contact layer disposed atop the first metallic mirror; and
a second metallic contact layer disposed atop the first metallic contact layer; wherein:
a first seed layer is disposed between the first metallic contact layer and the first metallic mirror; and
a second seed layer is disposed between the first metallic contact layer and the second metallic contact layer;
the radiation-emitting semiconductor chip comprises a radiation exit face having a multitude of emission regions; and
the first metallic mirror has a multitude of cutouts that each define a lateral extent of one of the emission regions.

2. The radiation-emitting semiconductor chip as claimed in claim 1, further comprising
a multitude of second metallic mirrors, each of which can be used to embed charge carriers into the second semiconductor layer; and
a multitude of third metallic contact layers; wherein:
one of the third metallic contact layers is disposed atop each of the second metallic mirrors and
a third seed layer is disposed in each case between the first metallic contact layers and the second metallic mirrors.

3. The radiation-emitting semiconductor chip as claimed in claim 1,
wherein the second metallic contact layer surrounds all second metallic mirrors in lateral directions.

4. The radiation-emitting semiconductor chip as claimed in claim 1, further comprising a first insulating layer disposed between the first metallic mirror and/or the second metallic mirror and the semiconductor layer sequence.

5. The radiation-emitting semiconductor chip as claimed in claim 1, further comprising an interlayer disposed atop the first insulating layer .

6. The radiation-emitting semiconductor chip as claimed in claim 1, further comprising a second insulating layer disposed between the first metallic contact layer and the third metallic contact layers.

7. The radiation-emitting semiconductor chip as claimed in claim 1, further comprising a current spreading layer disposed between the second metallic mirror and the semiconductor layer sequence.

8. The radiation-emitting semiconductor chip as claimed in claim 1, wherein a radiation exit face of the semiconductor layer sequence is free of any growth substrate.

9. A method of producing a radiation-emitting semiconductor chip, wherein the method comprises:
providing a semiconductor layer sequence having a first semiconductor layer and a second semiconductor layer;
creating a first recess that exposes regions of the first semiconductor layer;
creating a first metallic mirror in the first recess;
applying a first seed layer to the first metallic mirror;
depositing a first metallic contact layer on the first seed layer;
applying a second seed layer to the first metallic contact layer;
depositing a second metallic contact layer on the second seed layer;
applying a first insulating layer to the semiconductor layer sequence; and
creating a multitude of second recesses in the first insulating layer that each expose regions of the second semiconductor layer.

10. The method as claimed in claim 9, wherein the first recess extends along grid lines of a regular grid.

11. The method as claimed in claim 9, further comprising :
creating a second metallic mirror in any one of the second recesses;
applying a third seed layer to any one of the second metallic mirrors; and
depositing a third metallic contact layer on any one of the third seed layers.

12. The method as claimed in claim 9, further comprising planarizing the second metallic contact layer and the third metallic contact layers.

13. The method as claimed in claim 11, further comprising depositing the first metallic contact layer, the second metallic contact layer and/or the third metallic contact layers; wherein the depositing occurs by electroplating.

14. The method as claimed in claim 9, further comprising applying one solder layer atop the second metallic contact layer and one atop the third metallic contact layers.

15. The method as claimed in claim 9, further comprising applying an auxiliary carrier atop the second metallic contact layer and the third metallic contact layers.

16. The method as claimed in claim 9, wherein a growth substrate of the semiconductor layer sequence is detached.
